(19) United States
(12) Patent Application Publication
(10) Pub. No.: US 2026/0271399 A1
(43) Pub. Date: Sep. 10, 2026

(54) MASK PLATE, DISPLAY PANEL, AND DISPLAY DEVICE

(71) Applicant: Tianma Advanced Display Technology Institute (Xiamen) Co.,Ltd., Xiamen (CN)

(72) Inventors: Zhibo YANG, Xiamen (CN); Yangui FENG, Xiamen (CN); Bo ZHOU, Xiamen (CN); Ying LIU, Xiamen (CN)

(21) Appl. No.: 19/249,345

(22) Filed: Jun. 25, 2025

(30) Foreign Application Priority Data
Mar. 6, 2025 (CN) 202510264571.4

(51) Int. Cl. H10D 86/01; C23C 14/04; C25D 5/02

(52) U.S. Cl. CPC H10D 86/0231; C23C 14/042; C25D 5/022

(57) ABSTRACT

A mask plate includes a support layer; a patterned layer including a plurality of hollow structures and located on a side of the support layer; a first protective layer, located on a side of the support layer away from the patterned layer; and a second protective layer, located on a side of the patterned layer away from the support layer.

### CROSS-REFERENCE TO RELATED APPLICATION

This application claims the priority of Chinese Patent Application No. CN 2025102645714, filed on Mar. 6, 2025, the entire content of which is incorporated herein by reference.

### FIELD OF THE DISCLOSURE

The present disclosure relates to the field of display technology, and in particular to a mask plate and a method for forming the same, a display panel and a method for forming the same, and a display device thereof.

### BACKGROUND

In display technology, narrow bezels and spliced displays have become the main development trends. In related technologies, the realization of narrow bezels and seamless spliced displays mainly relies on side/back wiring technology. However, the side/back wirings are often formed by laser etching, which has a complex production process and a single method and also has problems such as low yield and poor reliability.

### SUMMARY OF THE DISCLOSURE

One embodiment of the present disclosure provides a mask plate. The mask plate includes a support layer; a patterned layer, including a plurality of hollow structures and located on a side of the support layer; a first protective layer, located on a side of the support layer away from the patterned layer; and a second protective layer, located on a side of the patterned layer away from the support layer.

Another embodiment of the present disclosure provides a method for forming a mask plate. The method includes providing a first stack structure, the first stack structure at least including a support layer and a to-be-patterned layer; disposing a first protective layer on a side of the support layer away from the to-be-patterned layer; performing a patterning processing on the to-be-patterned layer to obtain a patterned layer; and disposing a second protective layer on a side of the patterned layer away from the support layer, wherein the mask plate includes the first protective layer, the support layer, the patterned layer and the second protective layer, which are stacked one over another.

Another embodiment of the present disclosure provides a method for forming a display panel by providing a mask plate. The mask plate includes a support layer; a patterned layer, including a plurality of hollow structures and located on a side of the support layer; a first protective layer, located on a side of the support layer away from the patterned layer; and a second protective layer, located on a side of the patterned layer away from the support layer. The mask plate containing the patterned layer is attached to a first side surface of the display panel, and to a back side and/or a second side surface, adjacent to the first side surface. Based on the mask plate, a patterned film layer is formed on at least one side of the display panel.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure. The drawings herein are incorporated into the specification and constitute a part of the specification, showing embodiments consistent with the present disclosure, and together with the specification, are used to explain the principles of the present disclosure.

In order to more clearly illustrate the technical solutions in the embodiments of the present disclosure or the prior art, the drawings required for use in the embodiments or the prior art description will be briefly introduced below. Obviously, for ordinary technicians in this field, other drawings can be obtained based on these drawings without creative labor.

FIG. 1 is a schematic diagram of a mask plate according to an embodiment of the present disclosure.

FIG. 2 is a schematic diagram of another mask plate according to an embodiment of the present disclosure.

FIG. 3 is a schematic diagram of another mask plate according to an embodiment of the present disclosure.

FIG. 4 is a schematic diagram of another mask plate according to an embodiment of the present disclosure.

FIG. 5 is a schematic diagram of another mask plate according to an embodiment of the present disclosure.

FIG. 6 is a schematic diagram of another mask plate according to an embodiment of the present disclosure.

FIG. 7 is a schematic diagram of another mask plate according to an embodiment of the present disclosure.

FIG. 8 is a schematic diagram of another mask plate according to an embodiment of the present disclosure.

FIG. 9 is a schematic diagram of another mask plate according to an embodiment of the present disclosure.

FIG. 10 is a schematic diagram of another mask plate according to an embodiment of the present disclosure.

FIG. 11 is a schematic diagram of another mask plate according to an embodiment of the present disclosure.

FIG. 12 is a schematic diagram of a method for forming a mask plate according to an embodiment of the present disclosure.

FIG. 13 is a schematic diagram of a structure corresponding to the method for forming the mask plate shown in FIG. 12.

FIG. 14 is a schematic diagram of a method for forming the patterned layer shown in FIG. 12.

FIG. 15 is a schematic diagram of a structure corresponding to a method for forming another mask plate according to an embodiment of the present disclosure.

FIG. 16 is a schematic diagram of a method for forming a display panel according to an embodiment of the present disclosure.

FIG. 17 is a schematic diagram of a method for attaching a mask plate to the display panel shown in FIG. 16.

FIG. 18 is a schematic diagram of a method for forming a patterned film layer on a side of the display panel shown in FIG. 16.

FIG. 19 is a schematic diagram of a structure corresponding to a method for forming a display panel according to an embodiment of the present disclosure.

FIG. 20 is a schematic diagram of a display panel according to an embodiment of the present disclosure.

FIG. 21 is a schematic diagram of a display device according to an embodiment of the present disclosure.

FIG. 22 is a schematic diagram of another display device according to an embodiment of the present disclosure.

### DETAILED DESCRIPTION

Reference will now be made in detail to exemplary embodiments of the disclosure, which are illustrated in the accompanying drawings. Wherever possible, the same reference numbers will be used throughout the drawings to refer to the same or like parts.

In order to more clearly understand the above-mentioned purpose, features, and advantages of the present disclosure, the scheme of the present disclosure will be further described below. It should be noted that, in the absence of conflict, the embodiments of the present disclosure and the features in the embodiments can be combined with each other.

In the following description, specific details are set forth to facilitate a full understanding of the present disclosure, but the present disclosure can also be implemented in other ways different from those described herein, which are encompassed within the scope of the present disclosure.

The present disclosure relates to the field of display technology, and specifically to a mask plate and a method for forming the same, a display panel and a method for forming the same, and a display device. In one embodiment, the mask plate includes: a support layer; a patterned layer containing a plurality of hollow structures and located on a side of the support layer; a first protective layer located on the side of the support layer away from the patterned layer; and a second protective layer located on the side of the patterned layer away from the support layer. The mask plate may be attached to the display panel to be processed, and may be used to form side and/or back wiring, which avoids the display panel directly undergoing laser and other high-temperature processes, reduces the risk of transistors in the display panel being damaged, and improves the yield and reliability. Compared with the laser etching method, the disclosed formation method is simplified and the formation process is reduced.

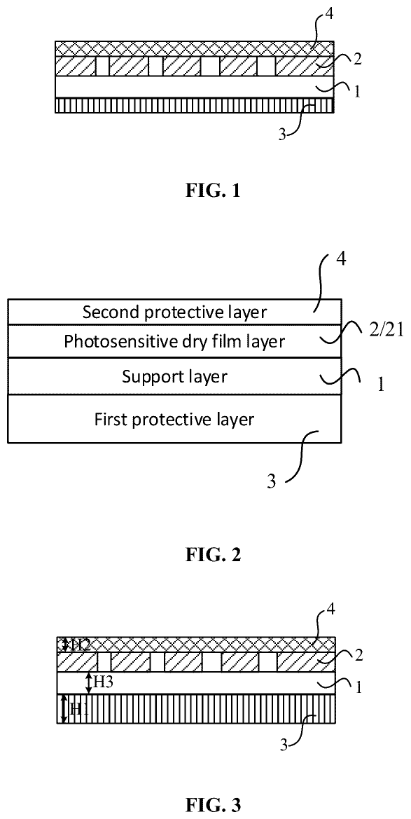

In FIG. 1, an exemplary mask plate includes: a support layer 1, a patterned layer 2, a first protective layer 3, and a second protective layer 4.

The patterned layer 2 includes a plurality of hollow structures, and the patterned layer 2 is located on one side of the support layer 1. The patterned layer 2 is a photosensitive material layer, which is patterned by photolithographic process with desired resolution capability. The support layer 1, as the substrate of the patterned layer 2, satisfies the requirements for coatability, light transmittance, and flexibility. When the patterned layer 2 is laminated to the non-identical plane of the display panel, and the support layer 1 has good flexibility and bendability, so that the patterned layer 2 is tightly laminated to the display panel to be processed, and the 3D lamination of the patterned layer 2 and the display panel is then realized. That is, the lamination mask patterning of non-identical planes is realized.

The first protective layer 3 is located on the side of the support layer 1 away from the patterned layer 2, that is, the support layer 1 is located between the patterned layer 2 and the first protective layer 3. The first protective layer 3 is used to protect the support layer 1 and also to provide support to the support layer 1 and the patterned layer 2, and has good flatness, low curling, low deformation and high temperature resistance.

The second protective layer 4 is located on the side of the patterned layer 2 away from the support layer 1, that is, the patterned layer 2 is located between the support layer 1 and the second protective layer 4. The second protective layer 4 is used to protect the patterned layer 2 from environmental pollution and the patterned structure of the patterned layer 2 from being damaged. The second protective layer 4 has a low adhesion to the patterned layer 2 and is easy to be peeled off.

In one embodiment, the mask plate is used to make a wiring on the side and/or back of the display panel. An exemplary production process includes: removing the first protective layer 3 and the second protective layer 4, retaining the double-layer structure of the support layer 1 and the patterned layer 4. The patterned layer 4 in the above double-layer structure faces the display panel and is attached to the side and/or back of the display panel. The support layer 1 is removed, and based on the patterned layer 2, a patterned film layer is formed on the display panel to be processed, followed by removing the patterned layer 2. The part of the film layer retained on the display panel is used as side/back wiring for the display panel/device.

It should be noted that the embodiment of the present disclosure does not limit the process of forming the patterned film layer, and all processes known to those skilled in the art can be used to form the patterned film layer, such as electrodeposition or evaporation. The wiring made using the mask plate provided In one embodiment corresponds to the hollow structure of the patterned layer 2.

The mask plate according to an embodiment of the present disclosure includes: a support layer 1; a patterned layer 2, including a plurality of hollow structures, and located on one side of the support layer 1; a first protective layer 3, located on the side of the support layer 1 away from the patterned layer 2; and a second protective layer 4, located on the side of the patterned layer 2 away from the support layer 1. Thus, the mask is attached to the display panel to be processed for making side/back wiring, which avoids the display panel directly experiencing laser and other high-temperature processes, reduces the risk of transistor damage, and improves the yield and reliability; at the same time, compared with the laser etching method, the manufacturing method is simple and the process is short.

In some embodiments, the line/space resolution of the patterned layer 2 ranges from 15/15 μm to 200/100 μm.

Among them, “line” refers to the line width of the wiring, and “space” refers to the gap width between the lines. Therefore, the line/space resolution can also be defined as “line width/line spacing”. The line/space resolution refers to the ability of the mask to form a pattern after exposure and development, which mainly depends on the patterned layer 2.

In some embodiments, as shown in FIG. 2, the patterned layer 2 includes a photosensitive dry film layer 21.

The photosensitive dry film layer 21 has a photosensitive patterning property. Exemplarily, the material of the photosensitive dry film layer 21 includes a dry film photoresist (DFR) layer.

In some embodiments, as shown in FIG. 3, the thickness H1 of the first protective layer 3 is greater than the thickness H3 of the support layer 1; and/or, the thickness H1 of the first protective layer 3 is greater than the thickness H2 of the second protective layer 4.

In one embodiment, the first protective layer 3 has a large thickness to meet the stable control of the total pitch/line width of the mask during patterning, storage and/or transportation processes, so that the deformation of the mask is less than the minimum allowable deformation, so as to ensure high-precision alignment with the rigid glass conduction contact point during use.

Exemplarily, as shown in FIG. 3, the thickness H1 of the first protective layer 3 is greater than the thickness H3 of the support layer 1, that is, H1>H3; and the thickness H1 of the first protective layer 3 is greater than the thickness H2 of the second protective layer 4, that is, H1>H2.

In some embodiments, the viscosity coefficient of the support layer 1 is 0-10 gf/25 mm, and the tensile strength is greater than 140 MPa.

When making the wiring, it is necessary to attach the mask plate that only retains the support layer 1 and the patterned layer 2 to the display panel to be processed, and remove the support layer 1 after attaching. The support layer 1 has the characteristics of low adhesion and low deformation/stretch resistance, and the adhesion between the support layer 1 and the patterned layer 2 is small. The support layer 1 can be removed by a slight external force, and the support layer 1 will not remain, and the patterned layer 2 will not be damaged.

In some embodiments, the material of the support layer 1 includes polyester (PET) film.

Exemplarily, as shown in FIG. 4, in the mask plate, the support layer 1 includes a polyester (PET) film layer 11.

In some embodiments, as shown in FIG. 3, the thickness H3 of the support layer 1 is 10-20 μm.

In one embodiment, the thickness H3 of the support layer 1 is negatively correlated with the bendability. The smaller the thickness H3, the easier the support layer 1 is to bend. The larger the thickness H3, the less likely the support layer is to bend.

Exemplarily, when the side and back wiring are made at the same time, the mask plate retaining the support layer 1 and the patterned layer 2 needs to be bent and attached to the side and back of the display panel. The mask plate retaining the support layer 1 and the patterned layer 2 uses the bendability of the support layer 1 to achieve non-same plane attachment of the patterned layer 2 and the display panel, that is, 3D attachment, thereby achieving non-same plane patterning.

In some embodiments, the viscosity coefficient of the first protective layer 3 is 0-10 gf/25 mm, and the tensile strength is greater than 140 MPa.

In one embodiment, before the mask plate is attached to the display panel to be processed, the first protective layer 3 needs to be removed. The first protective layer 3 has the characteristics of low viscosity and low deformation/tensile resistance. The adhesion between the first protective layer 3 and the support layer 1 is small. When the first protective layer 1 is removed, no residue will remain, and the support layer 1 will not be damaged.

In some embodiments, the material of the first protective layer 3 includes a blue polyester film or a white polyester film.

In one embodiment, the material of the first protective layer 3 includes a polyester film, and the appearance color can be blue or white.

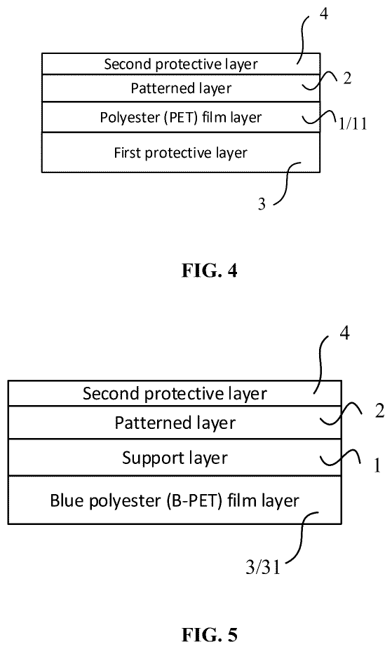

For example, as shown in FIG. 5, in the mask plate, the first protective layer 3 includes a blue polyester (B-PET) film layer 31.

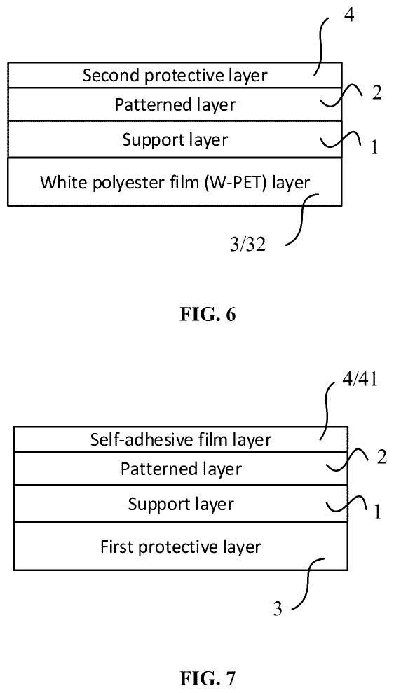

For example, as shown in FIG. 6, in the mask plate, the first protective layer 3 includes a white polyester film (W-PET) layer 32.

It should be noted that FIG. 5 or FIG. 6 only shows that the color of the first protective layer 3 is blue or white, but does not constitute a limitation on the mask plate provided by the embodiment of the present disclosure. In other embodiments, the first protective layer 3 can also be set as a polyester film layer of other colors, such as a transparent polyester film layer.

In some embodiments, as shown in FIG. 3, the thickness H1 of the first protective layer 3 is 50-200 μm.

In one embodiment, the first protective layer 3 is set to have a larger thickness, and H1 is set to be ≥50 μm, so as to meet the stable control of the total pitch/line width of the mask during the patterning formation, storage and transportation process, so that the deformation of the mask is less than the minimum allowable deformation, so as to ensure the high-precision alignment of the contact point with the rigid glass during use; at the same time, the thickness H1 of the first protective layer 3 is positively correlated with the production cost, and H1 is set to be ≤200 μm, which is conducive to controlling the production cost.

In some embodiments, the temperature resistance of the first protective layer 3 is greater than or equal to 100° C.

In one embodiment, the first protective layer 3 has a certain temperature resistance. In this way, the first protective layer 3 is not easy to deform and curl in a high temperature environment, which provides a flattening support effect to the support layer 1 and the patterned layer 2.

In some embodiments, as shown in FIG. 7, the second protective layer 4 includes a self-adhesive film layer 41.

In one embodiment, the self-adhesive film layer 41 is a weak adhesive film, which can be attached to the patterned layer 2 under the action of vacuum adsorption or electrostatic adsorption, and no additional adhesive is required to prevent the adhesive component from contaminating the patterned layer 2 or the adhesive from dissolving in the patterned layer 2. The self-adhesive film layer 41 has a low adhesive force, and while protecting the patterned layer 2 from environmental pollution, its adhesive force will not destroy the patterned structure of the patterned layer 2.

In some embodiments, the material of the second protective layer 4 includes polypropylene or polyethylene.

In one embodiment, polypropylene or polyethylene has self-adhesiveness, and polyethylene and polypropylene are used to prepare the second protective layer 4. There is no need to set an adhesive layer. The second protective layer 4 can be adsorbed on the patterned layer 2 under the action of vacuum adsorption or electrostatic adsorption; at the same time, the adhesive force of polypropylene or polyethylene is low, so that the second protective layer 4 is easy to be peeled off without damaging the patterned layer 2.

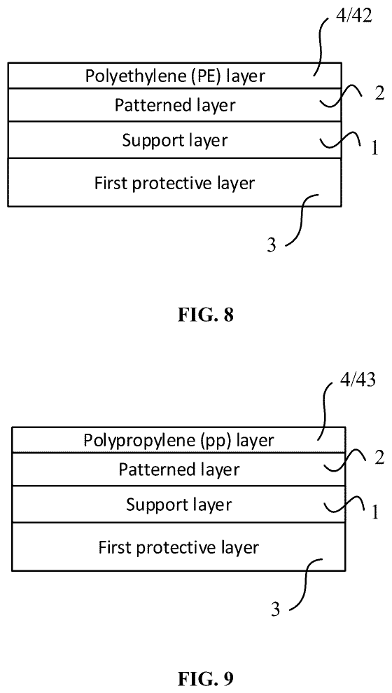

For example, as shown in FIG. 8, in the mask plate, the second protective layer 4 includes a polyethylene (PE) layer 42.

Exemplarily, as shown in FIG. 9, in the mask plate, the second protective layer 4 includes a polypropylene (PP) layer 41.

In some embodiments, the viscosity coefficient of the second protective layer 4 is 0-5 gf/25 mm.

In one embodiment, the viscosity coefficient of the second protective layer 4 is in the range of 0-5 gf/25 mm, and its viscosity is low, and it is easy to be peeled off without damaging the patterned layer 2.

In some embodiments, as shown in FIG. 3, the thickness H2 of the second protective layer 4 is 20-80 μm.

In one embodiment, the thickness H2 of the second protective layer 2 is set to be greater than or equal to 20 μm, that is, H2≥20 μm, to meet the strength of the second protective layer 2 with a protective effect, and the thickness H2 of the second protective layer 2 is set to be less than or equal to 80 μm, that is, H2≤80 μm, which is conducive to controlling the production cost on the one hand.

In some embodiments, the thickness of the patterned layer 2 is 15-30 μm.

In one embodiment, the thickness of the patterned layer 2 is related to the thickness of the routing. The routing thickness made using the mask provided In one embodiment is 15-30 μm.

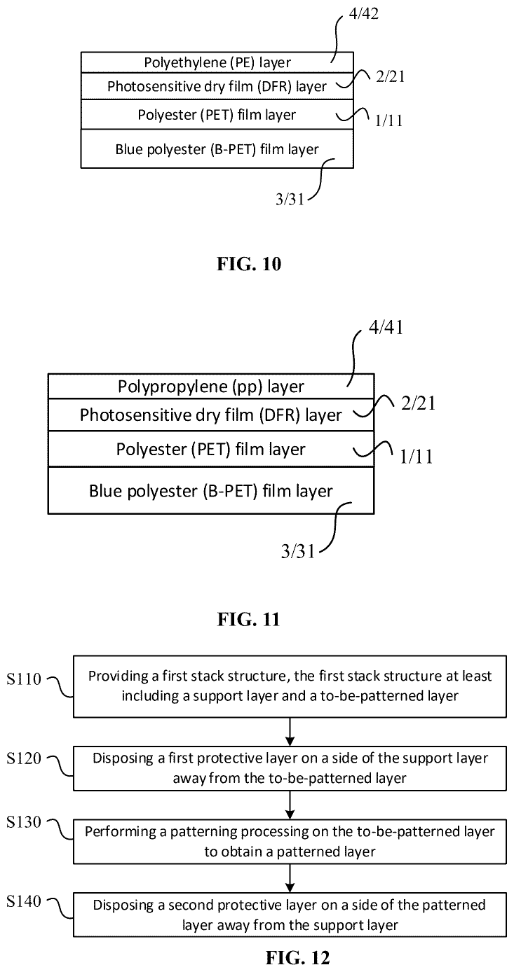

For example, as shown in FIG. 10, the mask includes: a polyethylene (PE) layer 42, a photosensitive dry (e.g., DFR) film layer 21, a polyester (PET) film layer 11, and a blue polyester (B-PET) film layer 31.

For example, as shown in FIG. 11, the mask includes: a polypropylene (PP) layer 41, a photosensitive dry (including DFR) film layer 21, a polyester (PET) film layer 11, and a blue polyester (B-PET) film layer 31.

Based on the same disclosure concept, the embodiment of the present disclosure also provides a method for forming a mask. The mask provided in the above embodiment is formed based on the method for forming the mask, which has corresponding beneficial effects. To avoid repeated description, it will not be repeated here.

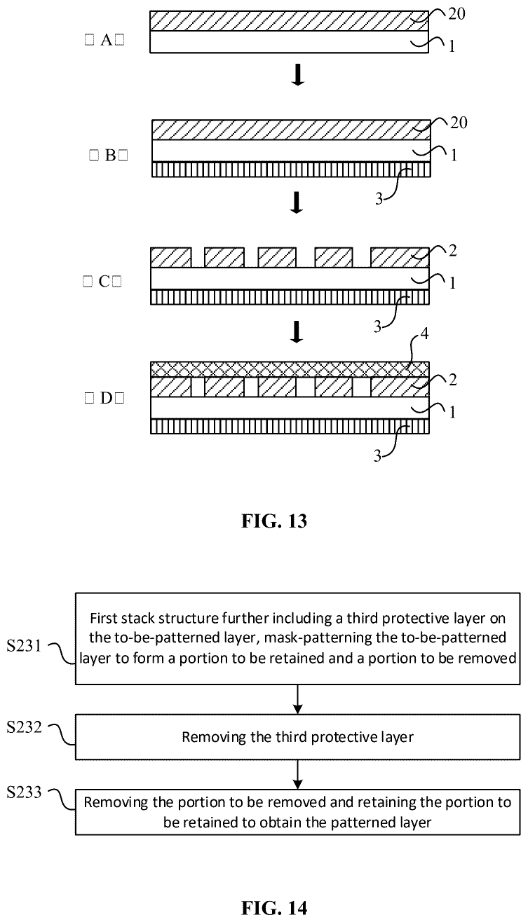

In some embodiments, as shown in FIGS. 12-13, the method for forming the mask plate includes the following exemplary steps.

In S110, a first stack structure is provided, the first stack structure at least includes a support layer and a to-be-patterned layer.

Exemplarily, as shown in step (A) in FIG. 13, the first stack structure includes a support layer 1 and a to-be-patterned layer 20, the support layer 1 serving as a substrate for the to-be-patterned layer 20, and the to-be-patterned layer 20 being entirely covered on one side surface of the support layer 1.

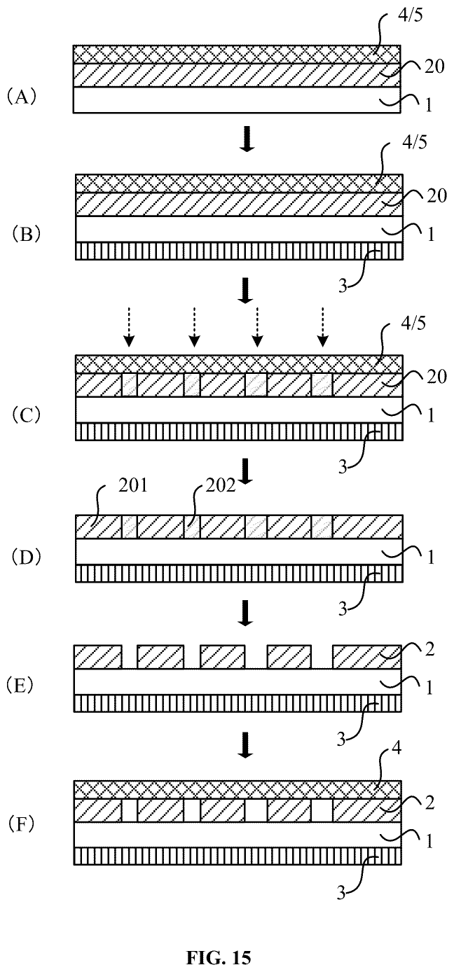

Exemplarily, as shown in step (A) in FIG. 15, the first stack structure including a support layer 1, a to-be-patterned layer 20, and a second protective layer 4, the support layer 1 serves as a substrate for the to-be-patterned layer 20, the to-be-patterned layer 20 is entirely covered on one side surface of the support layer 1, and the second protective layer 4 covers the side surface of the to-be-patterned layer 20 away from the support layer 1.

In S120, a first protective layer is disposed on the side of the support layer away from the to-be-patterned layer.

As shown in step (B) in FIG. 13, the first protective layer 3 is located on the surface of the support layer 1 on the side away from the to-be-patterned layer 20. That is, the support layer 1 is located between the to-be-patterned layer 20 and the first protective layer 3. The first protective layer 3 is used to protect the support layer 1 and also to provide support to the support layer 1 and the to-be-patterned layer 20, and has good flatness, low curling, low deformation, and high temperature resistance.

It should be noted that the present embodiment does not limit the formation process of the first protective layer 3, and all processes known to those skilled in the art, such as coating or hot pressing, can be used and encompassed within the scope of the present disclosure.

In S130, the to-be-patterned layer is patterned to obtain a patterned layer.

As shown in step (C) in FIG. 13, the patterned layer 2 obtained herein includes a plurality of hollow structures.

It should be noted that the present embodiment does not limit the process of patterning, and all processes known to those skilled in the art, such as exposure and development, can be used and encompassed within the scope of the present disclosure.

In S140, a second protective layer is disposed on the side of the patterned layer away from the support layer.

As shown in step (D) in FIG. 13, the second protective layer 4 is located on the side of the patterned layer 2 away from the support layer 1, and the second protective layer 4 is used to protect the patterned layer 2 from environmental pollution and scratches by hard objects. Combined with FIG. 1, the mask plate obtained in this step includes a first protective layer 3, a support layer 1, a patterned layer 2 and a second protective layer 4 stacked from bottom to top.

In some embodiments, as shown in step (A) in FIG. 15, the first stack structure also includes a third protective layer 5, which may be same or different than the second protective layer 4, located on the side of the to-be-patterned layer 20 away from the support layer 1, and the third protective layer 5 covers the to-be-patterned layer 20 in its entirety to avoid contaminating the to-be-patterned layer 20 during the formation of the mask plate.

As shown in FIG. 14, patterning the to-be-patterned layer includes the following exemplary steps.

In S231, the to-be-patterned layer on the side of the third protective layer is exposed by using a photolithographic mask to form a portion to be retained and a portion to be removed.

In one embodiment, the third and/or second protective layer 5/4 is light-transmissive.

As shown in step (C) in FIG. 15, the to-be-patterned layer 20 is exposed from one side of the second protective layer 4, such as by laser irradiation or ultraviolet light irradiation exposure. The part of the patterned layer 20 that has been exposed undergoes a qualitative change, and the part that has not been exposed does not change.

In one embodiment, the material of the patterned layer 20 includes a positive photosensitive material and a negative photosensitive material. If the material of the patterned layer is a positive photosensitive material, the exposed part of the patterned layer 20 softens in the developer and can be dissolved in the developer, and this part of the patterned layer 20 is the part to be removed, while the part of the patterned layer that has not been exposed is retained, that is, the part to be retained. If the patterned layer 20 is a negative photosensitive material, the exposed part of the patterned layer 20 becomes insoluble and hardens due to cross-linking, and this part of the patterned layer 20 cannot be washed away in the developer, that is, the part to be retained, and the unexposed patterned layer 20 is dissolved in the developer and removed, that is, the part to be removed.

S232, the third protective layer is removed.

As shown in step (D) in FIG. 15, the second protective layer 4 is removed to expose the surface of the patterned layer 20 that is away from the support layer 1.

In one embodiment, the second protective layer 4 is retained before exposure to protect the exposure surface of the to-be-patterned layer 20 from being polluted by the environment, which is conducive to improving the yield. After exposure, the second protective layer 4 is removed so that the developer contacts the to-be-patterned layer 20 in the subsequent steps, for removing the portion to be removed 202 and retaining the portion to be retained 201.

S233, the portion to be removed is removed, and the portion to be retained forms the patterned layer.

As shown in step (E) in FIG. 15, the mask obtained in the above steps is developed, the portion to be removed 202 is dissolved in the developer and removed, and the portion to be retained 201 is not dissolved in the developer and retained, thereby obtaining the patterned layer 2; the hollow structure in the patterned layer 2 corresponds to the portion to be removed 202.

As shown in step (E) in FIG. 15, the mask obtained in the above steps is developed, the portion to be removed 202 is dissolved in the developer and removed, and the portion to be retained 201 is not dissolved in the developer and retained, thereby obtaining the patterned layer 2; the hollow structure in the patterned layer 2 corresponds to the portion to be removed 202.

In some embodiments, “disposing a second protective layer on the side of the patterned layer away from the support layer” includes the following steps.

The second protective layer is attached on the side of the patterned layer away from the support layer.

As shown in step (F) in FIG. 15, after obtaining the patterned layer 2, the second protective layer 4 is attached (or reattached in some embodiments) to the side of the patterned layer 2 away from the support layer 1 to protect the patterned layer 2 from environmental pollution and the patterned structure from being destroyed.

In some embodiments, the second protective layer is a light-transmitting layer.

Exemplarily, the second protective layer 4 is a transparent layer, and the exposure light source can pass through the second protective layer 4 and perform exposure treatment on the designated position of the patterned layer 20.

Based on the above embodiments, the present disclosure also provides a method for forming a display panel. The method for forming a display panel uses any of the above mask plates or a mask plate formed by any of the above formation methods to prepare a display panel, which has corresponding beneficial effects. To avoid repeated description, it is not repeated here.

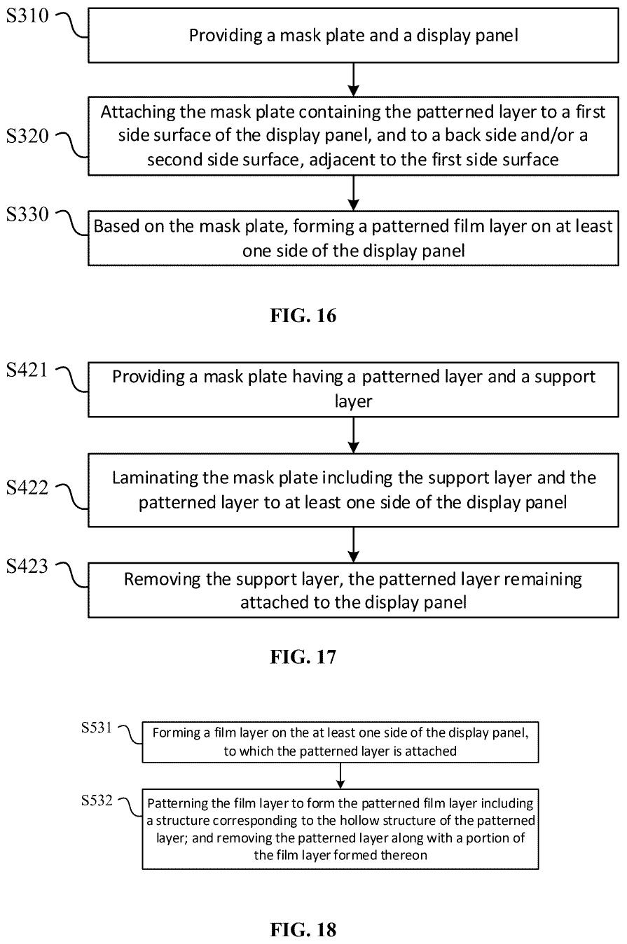

In some embodiments, as shown in FIG. 16, the method for forming a display panel includes the following exemplary steps.

In S310, a mask plate and a display panel to be processed are provided.

The mask plate includes any of the mask plates provided in the above embodiments, or the mask plate is formed based on any of the above mask plate formation methods.

In S320, the mask plate containing the patterned layer is attached (e.g., laminated, adhered, etc.) to a first side surface of the display panel, and to a back side and/or a second side surface, adjacent to the first side surface.

The mask plate retaining the patterned layer 2 is attached to the side of the display panel 5 for making side wiring; the mask plate retaining the patterned layer 2 is attached to the back of the display panel 5 adjacent to the side for making back wiring; the mask plate retaining the patterned layer 2 is attached to the back and side of the display panel 5 adjacent to the side for making back wiring and side wiring at the same time.

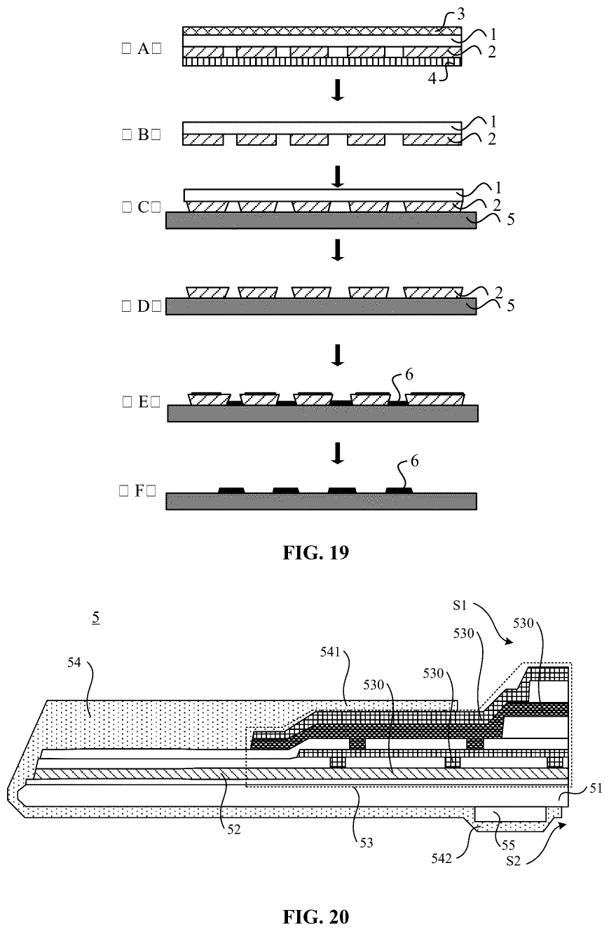

Exemplarily, as shown in step (C) in FIG. 19, one side of the patterned layer 2 faces the display panel, and the mask plate retaining the patterned layer 2 is attached to the display panel 5.

In S330, based on the mask plate, a patterned film layer is formed on at least one side of the display panel.

The patterned film layer is used as the wiring, and the wiring corresponds to the hollow structure of the patterned layer 2.

In this operation, the patterned layer 2 of the mask plate is used as a mask to form a patterned film layer on the side, back, or side and back of the display panel, thereby forming side/back wiring.

It should be noted that this embodiment aims to emphasize the implementation of mask patterning on non-identical planes of the display panel 5, and the non-identical planes include but are not limited to the side and back, multiple different sides, side and front, front, side and back, and at least two planes that are not in the same plane.

In some embodiments, as shown in FIG. 17, “attaching the mask plate retaining the patterned layer to the side of the display panel, and to the back and/or side adjacent to the side” includes the following steps.

In S421, the patterned layer and support layer of the mask plate are retained or otherwise provided.

As shown in steps (A) to (B) in FIG. 19, the first protective layer 3 and the second protective layer 4 are removed from both sides of the mask plate, and the patterned layer 2 and the support layer 1 are retained.

In S422, the mask plate with the support layer and the patterned layer is laminated to the at least one side of the display panel.

As shown in step (C) in FIG. 19, the first protective layer 3 and the second protective layer 4 are removed from both sides of the mask plate, and the patterned layer 2 and the support layer 1 are retained. The patterned layer 2 faces the display panel 5 to be processed, and the patterned layer 2 is attached to the display panel 5 to be processed.

It should be noted that the present disclosure embodiment does not limit the bonding process, and all bonding processes known to those skilled in the art can be used, such as alignment hot pressing bonding. The patterned layer 2 is not limited to being attached to the side of the display panel, but can also be attached to other planes other than the side, such as the back or the front.

In S423, the support layer is removed, with the patterned layer remaining attached to the display panel.

As shown in step (D) in FIG. 19, the support layer 1 of the mask plate is removed, only retaining the patterned layer 2 with a hollow structure on the display panel 5.

In some embodiments, as shown in FIG. 18, “forming a patterned film layer on at least one side of the display panel based on a mask plate” includes the following steps.

In S531, a film layer is formed on the at least one side of the display panel and on the patterned layer attached thereto.

As shown in step (E) in FIG. 19, a film layer is formed on the side of the patterned layer 2 away from the display panel 5, and the formed film layer covers the patterned layer 2 and the display panel 5 exposed by the hollow structure.

In S532, the film layer is patterned to form the patterned film layer including a structure corresponding to the hollow structure of the patterned layer; and the patterned layer along with a portion of the film layer formed thereon are removed.

As shown in step (F) in FIG. 19, while removing the patterned layer 2, the film layer covering the patterned layer 2 is also removed, and the retained film layer is the patterned film layer 6, and the patterned film layer 6 corresponds to the hollow structure of the patterned layer 2.

The disclosed embodiment does not limit the process of removing the patterned layer 2, and all processes/methods known to the technicians can be used to remove the patterned layer 2. Exemplarily, the patterned layer 2 is removed by hand-tearing, and the edge of the patterned film layer obtained by this method is uneven and irregularly serrated.

On the basis of the above-mentioned embodiments, the embodiment of the present disclosure also provides a display panel, which is formed based on any of the above-mentioned methods for forming the display panel, and has corresponding beneficial effects. To avoid repeated description, it is not repeated here.

Exemplarily, as shown in FIG. 20, the display panel 5 may include a light-emitting surface S1 (i.e., the front surface) and a backlight surface S2 (i.e., the back surface), and the light-emitting surface S1 is the side of the display panel 5 that displays the display screen to the user. The display panel 5 may also include: a substrate 51 and a lead wire 52. The lead wire 52 is located on one side of the substrate 51. The lead wire 52 may include at least part of the functional signal lines such as the data line, the power line, the reset line, and the clock line. The lead wire 52 can be used to be electrically connected to an external test fixture, and at least part of the above-mentioned functional signal lines can be electrically connected to the external test fixture, thereby realizing the performance test of the display panel 5. In order to enable the functional signal line to be electrically connected to the IC and/or the flexible circuit board, the display panel 5 also includes a transfer electrode block 53. The transfer electrode block 53 serves as a transfer part between the functional signal line and the IC and/or the flexible circuit board. The transfer electrode block 53 includes at least two transfer electrodes 530 arranged in a direction perpendicular to the plane where the display panel 5 is located and located in different conductive film layers. Since the transfer electrode block 53 includes at least two stacked transfer electrodes 530, the stacked multiple transfer electrodes 530 can be in the same layer as at least part of the functional signal lines located in different film layers in the display panel 5, which facilitates the connection between the functional signal line and the transfer electrode block 53. For example, the transfer electrode block 53 to which the data line is connected includes a transfer electrode 530 in the same layer as the data line, and the data line and the transfer electrode 530 in the transfer electrode block 53 remain connected after etching, and no other structure is required for transfer, which reduces the process difficulty and improves the process reliability.

In addition, the lead wire 52 may also include a portion located in the same conductive film layer as at least one transfer electrode 530 in the transfer electrode block 53, so as to realize the electrical connection between the lead wire 52 and the functional signal line through the transfer electrode block 53. For example, as shown in FIG. 20, the lead wire 52 and the transfer electrode 530 located at the bottom of the transfer electrode block 53 and located in the same conductive film layer as the gate of the first transistor T1 are located in the same conductive film layer, then the lead wire 52 and the transfer electrode 530 in the transfer electrode block 53 remain connected after etching, and no other structure is required for transfer, which reduces the process difficulty and improves the process reliability.

As shown in FIG. 20, in order to reduce the frame of the display panel 5, the IC and/or flexible circuit board bound to the display panel 5 are bound to the display panel 5 on the backlight surface S2 side of the display panel 5. The display panel 5 also includes a connecting electrode 54 and an external electrode block 55. The external electrode block 55 is located on the backlight surface S2 side of the display panel 5. The external electrode block 55 is electrically connected to the functional signal line through the connecting electrode 54. Specifically, the end 541 of the connecting electrode 54 located on the light-emitting surface S1 side of the display panel 5 contacts the transfer electrode block 53 on the light-emitting surface S1 side of the display panel 5, the end 542 of the connecting electrode 54 located on the backlight surface S2 side of the display panel 5 contacts the external electrode block 55 on the backlight surface S2 side of the display panel 5 or serves as the external electrode block 55, and the portion of the connecting electrode 54 between the end 541 located on the light-emitting surface S1 side of the display panel 5 and the end 542 located on the backlight surface S2 side of the display panel 5 is routed at the side wall of the display panel 5.

The transfer electrode block 53 is an electrode block for realizing electrical connection between the external electrode block 55 and the lead wire and the functional signal line. The width of the transfer electrode block 53 is usually greater than the width of the signal line and the lead wire, which is convenient for the contact yield between the connection electrode 54 and the transfer electrode block 53.

In the display panel 5 according to an embodiment of the present disclosure, the connection electrode 54 can be prepared using the mask provided in the above embodiment of the present application, and the connection electrode 54 located on the front, back and side of the display panel 5 is formed at the same time; and at least one of the lead wire 52, the transfer electrode block 53, the transfer electrode 530, the external electrode block 55 and the functional signal line can also be formed using the mask provided in the above embodiment of the present application, which is not limited here.

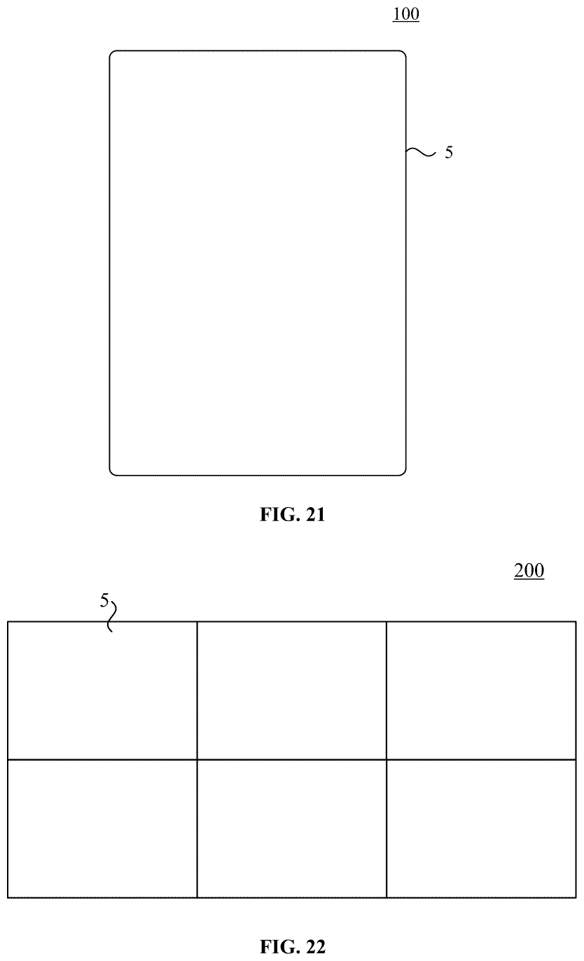

On the basis of the above embodiment, the embodiment of the present disclosure also provides a display device, as shown in FIG. 21, the display device 100 includes: the above display panel 5, which has corresponding beneficial effects, and the specific description of the display panel 5 in the above embodiment can be referred to, which will not be repeated here.

Among them, the display device 100 can be a mobile phone, a tablet, a computer, a television, a vehicle display device, an instrument display device, and other display devices with display functions, which are not specifically limited in the embodiments of the present disclosure.

On the basis of the above-mentioned embodiments, the embodiments of the present disclosure also provide a spliced display device, as shown in FIG. 22, the spliced display device 200 is a spliced display device 200 including the above-mentioned display panel 5. This type of spliced display device 200 can be a spliced large screen, which can be used in public information display (PID) scenes such as stations and airports.

The technical solution provided by the present disclosure has the following advantages. For example, the disclosed mask plate includes: a support layer; a patterned layer, including multiple hollow structures, and located on one side of the support layer; a first protective layer, located on the side of the support layer away from the patterned layer; a second protective layer, located on the side of the patterned layer away from the support layer. Therefore, the mask plate can be attached to the display panel for making side/back wiring, thereby avoiding the display panel directly experiencing laser and other high-temperature processes, reducing the risk of transistor damage, and improving yield and reliability. At the same time, compared with laser etching, the production method is simplified, and the process complexity is reduced.

It should be noted that in this article, relational terms such as “first” and “second” are only used to distinguish one entity or operation from another entity or operation, and do not necessarily require or imply any such actual relationship or order between these entities or operations. Moreover, the terms “include”, “comprises” or any other variation thereof are intended to cover non-exclusive inclusion, so that a process, method, article or device including a series of elements includes not only those elements, but also includes other elements not explicitly listed, or also includes elements inherent to such process, method, article or device. In the absence of further restrictions, an element defined by the sentence “includes one . . . ” does not exclude the presence of other identical elements in the process, method, article or device including the element.

The above is only a specific embodiment of the present disclosure, so that those skilled in the art can understand or implement the present disclosure. Various modifications to these embodiments will be obvious to those skilled in the art, and the general principles defined herein can be implemented in other embodiments without departing from the spirit or scope of the present disclosure. Therefore, the present disclosure will not be limited to the embodiments described herein, but will conform to the widest scope consistent with the principles and novel features disclosed herein.

The embodiments disclosed herein are exemplary only. Other applications, advantages, alternations, modifications, or equivalents to the disclosed embodiments are obvious to those skilled in the art and are intended to be encompassed within the scope of the present disclosure.

What is claimed is:

1. A mask plate, comprising:
a support layer;
a patterned layer, comprising a plurality of hollow structures and located on a side of the support layer;
a first protective layer, located on a side of the support layer away from the patterned layer; and
a second protective layer, located on a side of the patterned layer away from the support layer.

2. The mask plate according to claim 1, wherein a line/space resolution of the patterned layer ranges from 15/15 μm to 200/100 μm.

3. The mask plate according to claim 2, wherein the patterned layer comprises a photosensitive dry film layer.

4. The mask plate according to claim 1, wherein a thickness of the first protective layer is greater than a thickness of the support layer, and/or the thickness of the first protective layer is greater than a thickness of the second protective layer.

5. The mask plate according to claim 4, wherein a viscosity coefficient of the support layer is 0-10 gf/25 mm, and a tensile strength is greater than 140 MPa.

6. The mask plate according to claim 5, wherein a material of the support layer includes polyester film.

7. The mask plate according to claim 4, wherein the thickness of the support layer is 10-20 μm.

8. The mask plate according to claim 4, wherein a viscosity coefficient of the first protective layer is 0-10 gf/25 mm, and a tensile strength is greater than 140 MPa.

9. The mask plate according to claim 8, wherein a material of the first protective layer includes blue polyester film or white polyester film.

10. The mask plate according to claim 4, wherein
the thickness of the first protective layer is 50-200 μm, and/or
the thickness of the second protective layer is 20-80 μm.

11. The mask plate according to claim 1, wherein the second protective layer includes a self-adhesive film layer.

12. The mask plate according to claim 11, wherein a material of the second protective layer includes polypropylene or polyethylene.

13. The mask plate according to claim 1, wherein
a thickness of the patterned layer is 15-30 μm.

14. A method for forming a mask plate, comprising:
providing a first stack structure, the first stack structure at least comprising a support layer and a to-be-patterned layer;
disposing a first protective layer on a side of the support layer away from the to-be-patterned layer;
performing a patterning processing on the to-be-patterned layer to obtain a patterned layer; and
disposing a second protective layer on a side of the patterned layer away from the support layer, wherein the mask plate comprises the first protective layer, the support layer, the patterned layer and the second protective layer, which are stacked one over another.

15. The method according to claim 14, wherein the first stack structure further includes a third protective layer located on the side of the to-be-patterned layer away from the support layer; and patterning the to-be-patterned layer comprises:
mask-patterning the to-be-patterned layer to form a portion to be retained and a portion to be removed;
removing the third protective layer; and
removing the portion to be removed and retaining the portion to be retained to obtain the patterned layer.

16. The method according to claim 15, wherein disposing the second protective layer on the side of the patterned layer away from the support layer comprising:
after removal of the third protective layer, laminating the second protective layer on the side of the patterned layer away from the support layer, wherein the second protective layer is same as the third protective layer.

17. The method according to claim 14, wherein the second protective layer is a light-transmitting layer.

18. A method for forming a display panel, comprises:
providing a mask plate, the mask plate comprising a support layer; a patterned layer, comprising a plurality of hollow structures and located on a side of the support layer; a first protective layer, located on a side of the support layer away from the patterned layer; and a second protective layer, located on a side of the patterned layer away from the support layer;
attaching the mask plate containing the patterned layer to a first side surface of the display panel, and to a back side and/or a second side surface, adjacent to the first side surface; and
based on the mask plate, forming a patterned film layer on at least one side of the display panel.

19. The method according to claim 18, wherein attaching the mask plate containing the patterned layer to the first side surface of the display panel, and to the back side and/or the second side surface adjacent to the first side surface comprising:
laminating the mask plate including the support layer and the patterned layer to the at least one side of the display panel; and
removing the support layer, wherein the patterned layer remains attached to the display panel.

20. The method according to claim 19, wherein based on the mask plate, forming the patterned film layer on the at least one side of the display panel comprises:
forming a film layer on the at least one side of the display panel and on the patterned layer attached thereto;
patterning the film layer on the at least one side of the display panel to form the patterned film layer, the patterned film layer comprising a structure corresponding to the hollow structure of the patterned layer; and
removing the patterned layer along with a portion of the film layer formed thereon.
